(19) United States
(12) Patent Application Publication
(10) Pub. No.: US 2022/0171377 A1
(43) Pub. Date: Jun. 2, 2022

(54) MOUNTED BOARD MANUFACTURING SYSTEM

(71) Applicant: Panasonic Intellectual Property Management Co., Ltd., Osaka (JP)

(72) Inventors: Taichi SHIMIZU, Osaka (JP); Eiji SHIGAKI, Fukuoka (JP)

(21) Appl. No.: 17/598,381

(22) PCT Filed: Mar. 13, 2020
(86) PCT No.: PCT/JP2020/011305

§ 371 Date: Sep. 27, 2021

(30) Foreign Application Priority Data
Mar. 29, 2019 (JP) 2019-068258

(51) Int. Cl. G05B 19/418; H05K 13/04

(52) U.S. Cl. CPC G05B 19/41885; G05B 2219/31263; H05K 13/04

(57) ABSTRACT

A mounted board manufacturing system that manufactures a mounted board, which is a board mounted with a component. The mounted board manufacturing system includes: at least one component loading device that executes a component loading operation for loading the component on a board; a rule base with which at least one machine parameter for executing the component loading operation performed by the at least one component loading device can be calculated; an operation information aggregator that aggregates, for each component data, results of processing executed by the at least one component loading device, together with operation information; and a calculation processor that selects, as actual training data, component data corresponding to an operation result that exceeds a predetermined reference, from the operation information aggregator, and estimates at least one machine parameter of a new component, using the actual training data, the rule base, and basic information of the new component.

### TECHNICAL FIELD

The present disclosure relates to a mounted board manufacturing system for a component mounter.

### BACKGROUND ART

A mounted board manufacturing system that manufactures a mounted board includes a component mounting line in which a component placement device which executes component loading operation for loading a component on a board is disposed. The component loading operation executed by the component placement device includes various work operations such as a suction operation for taking out a component from a component supplier using a suction nozzle, a recognition operation for recognizing the component that has been taken out by capturing an image of the component, a loading operation for transferring and loading the component onto the board, etc. In the above-described work operations, it is required to execute finespun operations for fine components with high accuracy and high efficiency, and thus machine parameters for executing each of the work operations in a good operation mode are set in advance according to the types of the components. Component data in which the machine parameters are associated with the types of the components are stored as a component library.

The component data is not necessarily set to an optimum value that allow the work operation to be executed in an optimum operating mode. It is thus necessary to correct the component data as needed in response to a problem that occurs during the component loading operation.

However, the operation of correcting component data requires a high level of expertise, such as specialized knowledge related to component placement and skills based on experience, and thus production sites are conventionally forced to spend a great amount of time and labor through trial and error. In other words, even when a problem such as a component recognition failure or a suction error occurs during the component loading operation, what parameter items should be corrected and how to do so have actually been determined depending on the operator's know-how. For this reason, in the case where an unskilled operator is in charge of the task of data correction, trial and error will be repeated due to inappropriate data correction. As a result, not only the work efficiency of data correction operation but also the improvement of the work quality of the component loading operation have been inhibited.

In view of the above, as a countermeasure, Patent Literature (PTL) 1 discloses a mounted board manufacturing system that corrects at least one machine parameter included in component data based on the performance of the component loading operation.

### CITATION LIST

### Patent Literature

[PTL 1] Japanese Unexamined Patent Application Publication No. 2019-4129

### SUMMARY OF INVENTION

### Technical Problem

However, with the mounted board manufacturing system disclosed by PTL 1, correction operation is performed on a component with a poor performance, and thus the correction operation will be performed only when a poor performance is confirmed after preliminarily performing the component loading operation. For that reason, in a situation where a new component that has no production record is used, operation time for preliminarily performing a component loading operation needs to be taken; that is, a man-hour to check the performance is required, every time a component is changed. As a result, a production efficiency is decreased.

In addition, in recent years, there is a method of outputting various parameters of a loading device for a new component or the like, by utilizing a machine learning technique using accumulated data. However, there are instances where a problem of causing confusion in the site occurs because values of various parameters which do not match the experience of a vendor or a skilled user are generated sometimes.

In view of the above, the present disclosure provides a mounted board manufacturing system capable of estimating an appropriate machine parameter for a new component without the need for a man-hour to check a performance.

### Solution to Problem

In order to achieve the above-described object, a mounted board manufacturing system according to one aspect of the present disclosure is a mounted board manufacturing system that manufactures a mounted board, which is a board mounted with a component. The mounted board manufacturing system includes: at least one component loading device that executes a component loading operation for loading the component on a board; a rule base with which at least one machine parameter for executing the component loading operation performed by the at least one component loading device can be calculated; an operation information aggregator that aggregates, for each component data, results of processing executed by the at least one component loading device, together with operation information; and an estimator that selects, as actual training data, component data that corresponds to an operation result that exceeds a predetermined reference, from the operation information aggregator, and estimates at least one machine parameter of a new component, using the actual training data, the rule base, and basic information of the new component.

It should be noted that these general or specific aspects may be implemented using a system, a method, an integrated circuit, a computer program, or a computer-readable recording medium such as a compact disc read-only memory (CD-ROM), or any combination of systems, methods, integrated circuits, computer programs, or recording media.

### Advantageous Effects of Invention

According to the present disclosure, it is possible to estimate an appropriate machine parameter for a new component without the need for a man-hour to check the performance.

### BRIEF DESCRIPTION OF DRAWINGS

FIG. 1 is a diagram explaining a configuration of a mounted board manufacturing system according to an embodiment.

FIG. 2 is a diagram illustrating an example of operation information aggregation data according to the embodiment.

FIG. 3 is a diagram explaining a data configuration of component data used in the mounted board manufacturing system according to the embodiment.

FIG. 4 is a diagram illustrating an example of a rule base set by a vendor according to the embodiment.

FIG. 5 is a diagram illustrating an example of the rule base set by a user according to the embodiment.

FIG. 6 is a diagram illustrating an example of actual training data according to the embodiment.

FIG. 7 is a flowchart illustrating the operation of the mounted board manufacturing system up to the start of production of new components.

FIG. 8 is a diagram illustrating an example of a graphical model of the statistical model according to Working example 1 of the embodiment.

FIG. 9 is a diagram illustrating an example of a graphical model of the statistical model according to Working example 2 of the embodiment.

FIG. 10 is a diagram for explaining adjustment of weight of a plurality of rules included in a rule base according to Working example 3 of the embodiment.

FIG. 11 is a diagram illustrating an example of a graphical model of a Gaussian process model.

FIG. 12 is a diagram illustrating an example of a graphical model of the statistical model according to Working example 4 of the embodiment.

FIG. 13 is a diagram illustrating an example of another graphical model of the statistical model according to Working example 4 of the embodiment.

FIG. 14 is a diagram illustrating an example of a graphical model of the statistical model according to Working example 5 of the embodiment.

FIG. 15 is a diagram illustrating an example of a graphical model of the statistical model according to Working example 6 of the embodiment.

FIG. 16 is a bubble chart indicating machine parameters estimated by a hybrid method according to the present disclosure.

FIG. 17 is component information indicated when one or more of the bubbles indicated in FIG. 16 are selected.

FIG. 18 is a cumulative sum chart indicating machine parameters estimated by the hybrid method according to the present disclosure.

### DESCRIPTION OF EMBODIMENTS

A mounted board manufacturing system according to one aspect of the present disclosure is a mounted board manufacturing system that manufactures a mounted board, which is a board mounted with a component. The mounted board manufacturing system includes: at least one component loading device that executes a component loading operation for loading the component on a board; a rule base with which at least one machine parameter for executing the component loading operation performed by the at least one component loading device can be calculated; an operation information aggregator that aggregates, for each component data, results of processing executed by the at least one component loading device, together with operation information; and an estimator that selects, as actual training data, component data that corresponds to an operation result that exceeds a predetermined reference, from the operation information aggregator, and estimates at least one machine parameter of a new component, using the actual training data, the rule base, and basic information of the new component.

According to this configuration, it is possible to estimate an appropriate machine parameter for a new component without the need for a man-hour to check the performance. Therefore, even in a situation where a new component that has no production record is used, it is not necessary to preliminarily take time to perform a component loading operation every time a component is changed, and thus it is possible to inhibit a decrease in production efficiency.

Here, the estimator: performs an estimation on the basic information of the new component using a Gaussian process regressor that has been learned using, as learning data, basic information of a component and a corresponding machine parameter value that are included in the component data that corresponds to the operation result that exceeds the predetermined reference, to generate a predictive distribution of machine parameters applicable to the new component; calculates a posterior distribution of the machine parameters applicable to the new component based on a fact that outputs of the rule base are generated from a normal distribution having, as the mean, the machine parameters applicable to the new component; and outputs a mean of the posterior distribution calculated, as a machine parameter to be applied to the new component among the machine parameters applicable to the new component.

According to this configuration, it is possible to estimate, before the component loading operation, an appropriate machine parameter for a new component in accordance with the experience of a vendor and a skilled user, without the need for a man-hour to check the performance. Therefore, even in a situation where a new component that has no production record is used, it is not necessary to preliminarily take time to perform a component loading operation every time a component is changed, and thus it is possible to inhibit a decrease in production efficiency.

In addition, for example, the rule base may include two or more rules that do not match and that produce different outputs, for calculating the at least one machine parameter of the new component.

In addition, for example, the estimator: may perform an estimation on the basic information of the new component using a Bayesian statistical model to generate a predictive distribution of machine parameters applicable to the new component; calculate a posterior distribution of the machine parameters applicable to the new component based on a fact that an output of the rule base is generated from a distribution having, as parameters, the machine parameters applicable to the new component; and output a mean of the posterior distribution calculated, as a machine parameter to be applied to the new component among the machine parameters applicable to the new component.

In addition, for example, the estimator: performs an estimation on the basic information of the new component using a Bayesian statistical model that has been learned using, as learning data, basic information of a component and a corresponding machine parameter value that are included in the component data that corresponds to the operation result that exceeds the predetermined reference, to generate a predictive distribution of machine parameters applicable to the new component; calculates a posterior distribution of the machine parameters applicable to the new component based on a fact that outputs of the two or more rules that do not match are generated from a distribution having, as parameters, the machine parameters applicable to the new component; and outputs a mean of the posterior distribution calculated, as a machine parameter to be applied to the new component among the machine parameters applicable to the new component.

In addition, for example, features of the component data that corresponds to the operation result that exceeds the predetermined reference may be different between the rule base and machine learning.

In addition, for example, the mounted board manufacturing system may further include: an interface section that displays: a machine parameter that is output by the estimator and is to be applied to the new component; and a machine parameter that is actually used for executing the component loading operation performed by the at least one component loading device.

Note that these general and specific aspects may be implemented using a system, a method, an integrated circuit, a computer program, or a computer-readable recording medium such as a compact disc read-only memory (CD-ROM), or any combination of systems, methods, integrated circuits, computer programs, or recording media.

The following describes in detail an embodiment according to the present disclosure, with reference to the drawings. Note that the embodiment described below presents a specific preferred example of the present disclosure. The numerical values, shapes, materials, structural components, the arrangement and connection of the structural components, steps, the processing order of the steps etc. described in the following embodiment are mere examples, and therefore do not limit the scope of the present disclosure. As such, among the structural elements in the following embodiment, structural elements not recited in any one of the independent claims which indicate the broadest concepts of the present disclosure are described as arbitrary structural elements of a preferred embodiment. In this Description and the drawings, structural elements having substantially identical functions or structures are assigned the same reference signs, and overlapping description thereof is omitted.

### EMBODIMENT

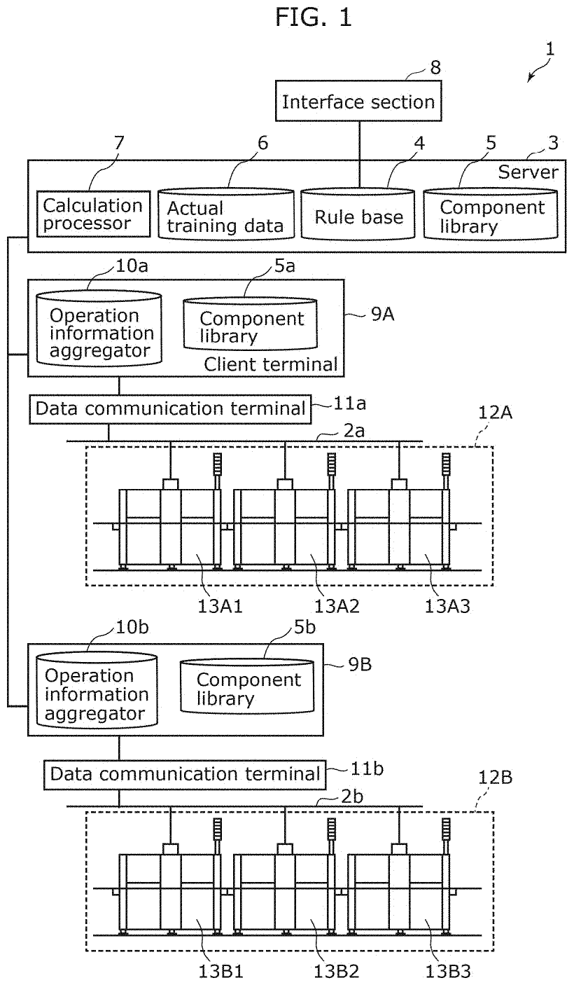

First, a configuration of mounted board manufacturing system 1 will be described with reference to FIG. 1.

### [Mounted Board Manufacturing System 1]

FIG. 1 is a diagram explaining a configuration of mounted board manufacturing system 1 according to the present embodiment. Mounted board manufacturing system 1 has a function of manufacturing a mounted board, which is a board mounted with a component. In FIG. 1, mounted board manufacturing system 1 includes a plurality of component mounting lines 12A and 12B (two component mounting lines in this case).

### [Component Mounting Lines 12A, 12B]

Component loading devices 13A1, 13A2, and 13A3 are arranged in component mounting line 12A, and component loading devices 13B1, 13B2, and 13B3 are arranged in component mounting line 12B. In other words, mounted board manufacturing system 1 includes at least one component loading device 13 that performs a component loading operation of loading a component on a board. Component loading devices 13A1, 13A2, and 13A3 are connected to each other by communication network 2a established by a local area network or the like. In addition, component loading devices 13A1, 13A2, and 13A3 are connected to client terminal 9A that includes component library 5a and operation information aggregator 10a via data communication terminal 11a.

Likewise, component loading devices 13B1, 13B2, and 13B3 are connected to each other by communication network 2b, and connected to client terminal 9B that includes component library 5b and operation information aggregator 10b via data communication terminal 11b.

It should be noted that, in the following description, when it is not necessary to distinguish between component mounting lines 12A and 12B, component mounting lines 12A and 12B will be collectively referred to simply as component mounting line 12. Likewise, when it is not necessary to distinguish between component loading devices 13A1, 13A2, and 13A3, and component loading devices 13B1, 13B2, and 13B3, component loading devices 13A1, 13A2, 13A3, 13B1, 13B2, and 13B3 will be collectively referred to simply as component loading device 13.

### [Client Terminals 9A, 9B]

Client terminals 9A and 9B include component libraries 5a and 5b and operation information aggregators 10a and 10b, as illustrated in FIG. 1.

Client terminals 9A and 9B are connected to server 3 via communication network 2 (2a, 2b) established by a local area network, the Internet (public line), or the like.

Data necessary for the production of mounted boards by component mounting lines 12A and 12B is downloaded to client terminals 9A and 9B, respectively, from server 3 via communication network 2. In other words, production data (not illustrated), which is production data of the mounted boards respectively produced by component mounting lines 12A and 12B and stored in server 3, is downloaded from server 3 to client terminals 9A and 9B via communication network 2. Here, the production data is data stored in server 3 and used for mounted boards produced in a factory in which component mounting lines 12A and 12B are included. In this production data, data necessary for producing mounted boards of one board type by component loading device 13 is specified. In production data, for example, a component name of a component to be mounted on the mounted board of the board type, a component code for identifying the component in the component library, a placement position and placement angle of the component on the mounted board are specified for each component to be mounted. In addition, in this production data, equipment condition data which indicates the conditions of an equipment side used for the production of the mounted board, i.e., the setting status or the like in component loading device 13 may be specified for each of the component names.

Likewise, among the component data stored in component library 5, the component data used for the mounted boards produced respectively by component mounting lines 12A and 12B are downloaded to component libraries 5a and 5b of client terminals 9A and 9B.

In component mounting lines 12A and 12B, the component loading operation is carried out using component libraries 5a and 5b at the time of production. When an error occurs during the component loading operation, the component data in component libraries 5a and 5b are changed by a user. It should be noted that the error here is, for example, an error in the suction operation when a component is taken out from the component supplier by vacuum suction using a loading head. In addition, the error here may also be an error in recognizing the component that has been taken out by capturing the component using a component recognition camera, a placement error in loading the component that has been taken out on the board using the loading head, or an error in determining a failure that is found in an inspection process at a later stage of the mounting line, etc.

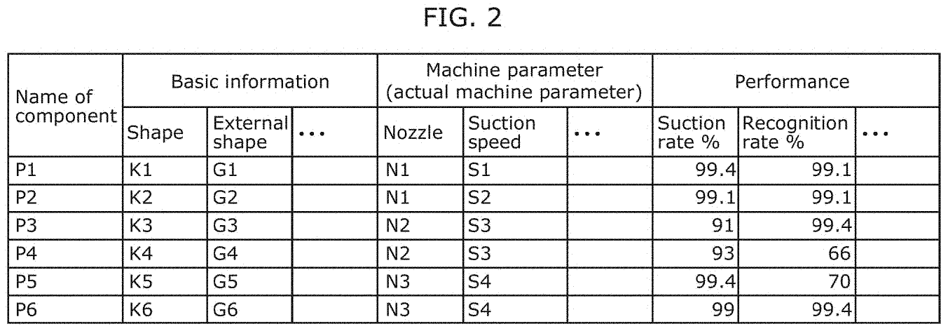

FIG. 2 is a diagram illustrating an example of operation information aggregation data according to the present embodiment.

Client terminals 9A and 9B include operation information aggregators 10a and 10b as described above. Operation information aggregators 10a and 10b aggregate, for each component data, results of the processing executed by component loading device 13, together with operation information.

More specifically, operation information aggregators 10a and 10b perform the processes of aggregating, for each component data, performances of the component loading operation carried out by component mounting lines 12A and 12B for the production of mounted boards, and accumulating the performances that have been aggregated as operation information aggregation data. Here, the performance of the component loading operation is the performance resulting from calculating an error rate, after aggregating the above-described errors for each component and further aggregating, for each component, the number of components loaded on the board which are not involved in the errors. In other words, the performance of the component loading operation is indicated by “suction rate %”, “recognition rate %”, “placement rate %”, “inspection error rate %”, etc., as indicated in an example of the operation information aggregation data illustrated in FIG. 2, for example. As described above, in the operation information aggregation data illustrated in FIG. 2, the performance of the component loading operation for each component is included as a result of the processing executed by component loading device 13. In addition, as illustrated in FIG. 2, a plurality of conditions of component basic information for each component and a plurality of machine parameters (actual machine parameters) actually applied in the component loading operation are included as operation information in the operation information aggregation data. The plurality of conditions of the component basic information correspond to the shape, size, etc. specified in the basic information of the component data, which will be described later. The plurality of conditions of the component basic information correspond to the shape, size, etc. specified in basic information 15 of component data 14, which will be described later. The plurality of machine parameters (actual machine parameters) correspond to the nozzle settings, suction, etc. specified in the machine parameters of the component data which will be described later, and the values of the component data as they are or the values updated by the user, etc. are included as the actual values.

### [Server 3]

Server 3 has the function of providing data of various types used in mounted board manufacturing system 1 to client terminals 9A and 9B. As illustrated in FIG. 1, for example, server 3 includes rule base 4, component library 5, actual training data 6, and calculation processor 7. Server 3 is wired or wirelessly connected to interface section 8. It should be noted that server 3 stores the above-described production data.

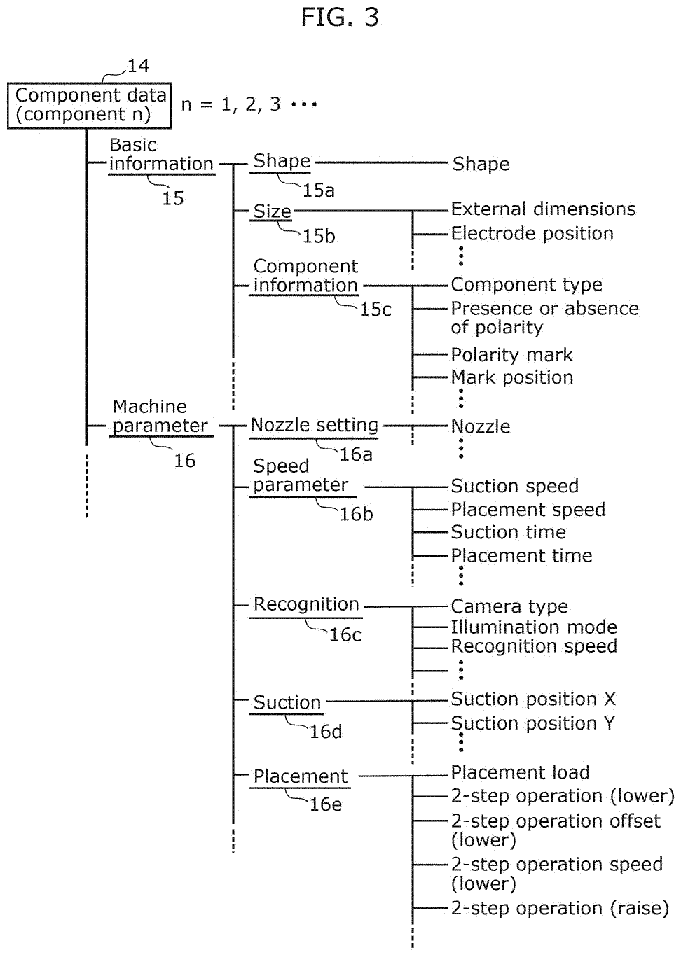

FIG. 3 is a diagram explaining a data configuration of component data 14 used in mounted board manufacturing system 1 according to the present embodiment.

Component library 5 is a compilation, in the form of a master library, of component data 14 (see FIG. 3) related to the components used for a mounted board produced in the above-described factory, and is included in server 3. Component library 5 is a library that stores a plurality of component data 14 each including at least one machine parameter for the component loading operation to be performed by component loading device 13 and basic information related to the component.

Here, as illustrated in FIG. 3, basic information 15 and machine parameter 16 are specified as large sort items in component data 14.

Basic information 15 is information that indicates an attribute unique to the component. FIG. 3 illustrates, as examples of the medium sort item of basic information 15, shape 15a, size 15b, and component information 15c.

Shape 15a is information related to the shape of the component. As a small sort item of shape 15a, “shape” that indicates an external shape of the component by shape segments such as quadrilateral, cylindrical, etc., is specified. As small sort items of size 15b, “external dimensions” that indicates the size of the component, “electrode position” that indicates a total number or position of electrodes for connection included in the component, etc. are specified. Component information 15c is the attribute information of the component. As small sort items of basic information 15, “component type” that indicates the type of the component, “presence or absence of polarity” that indicates the presence or absence of directionality in the external shape of the component, “polarity mark” that indicates the shape of a mark which is attached to the component when polarity is present, and “mark position” that indicates the position of the mark when the polarity mark is present.

Machine parameter 16 is a parameter for executing the component loading operation by component loading device 13. More specifically, machine parameter 16 is a control parameter for use in controlling component loading device 13 when component loading device 13 disposed on component mounting line 12 performs the component loading operation for the components specified in component data 14. Machine parameter 16 is estimated by server 3 using a hybrid method described below, in which both rule base 4 and component data that corresponds to a good performance in actual usage are utilized.

FIG. 3 illustrates, as examples of the medium sort item of machine parameter 16, nozzle setting 16a, speed parameter 16b, recognition 16c, suction 16d, and placement 16e.

Nozzle setting 16a is data related to the suction nozzle that is used in the case of sucking and holding the component. As a small sort item of nozzle setting 16a, “nozzle” that identifies the type of the suction nozzle that can be selected is specified. Speed parameter 16b is a control parameter related to the movement speed of the suction nozzle in the work operation of taking out the component by the suction nozzle and placing the component onto the board. As small sort items of speed parameter 16b, “suction speed” and “suction time” for sucking and holding a component, “placement speed” and “placement time” for placing the held component on the board, etc. are specified.

Recognition 16c is a control parameter related to the execution of a recognition process in which the component taken out by the suction nozzle from the component supplier is captured by the component recognition camera and recognized. As small sort items of recognition 16c, “camera type” which specifies the type of a camera for use in image capturing, “illumination mode” that indicates the mode of illumination used for image capturing, “recognition speed” at the time of recognizing the image acquired by image capturing, etc. are specified.

Suction 16d is a control parameter related to the suction operation when a component is taken out by the suction nozzle from the component supplier. As small sort items of suction 16d, “suction position X”, “suction position Y”, etc., each of which indicates the suction position when the suction nozzle is caused to land on the component are specified.

Placement 16e is a control parameter related to the loading operation in which a loading head that sucks and holds a component by the suction nozzle is moved to the board and the suction nozzle is caused to move up and down so as to place the component onto the board. As a small sort item of placement 16e, “placement load” that is the load that presses the component to the board when the suction nozzle is caused to move downward to land the component on the board. In FIG. 3, “2-step operation (lower)”, “2-step operation offset (lower)”, “2-step operation speed (lower)”, “2-step operation (raise)”, etc., each of which specifies an operation mode such as a switching height position, a high/low speed, or the like when the up and down operation to lower and raise the suction nozzle is performed by switching the speed of the up and down operation between two steps of high and low are further indicated as examples of the small sort item of placement 16e.

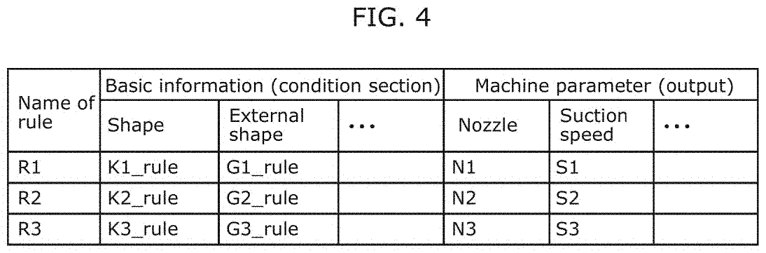

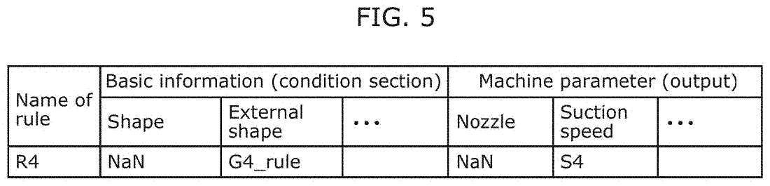

FIG. 4 is a diagram illustrating an example of the rule base that has been set by a vendor according to the present embodiment. FIG. 5 is a diagram illustrating an example of the rule base that has been set by a user according to the present embodiment.

Rule base 4 is a rule base that is held by server 3, with which at least one machine parameter can be calculated by being used by server 3. As indicated in FIG. 4, rule base 4 stores at least one rule including a condition section and an output.

The following describes rule base 4 with reference to FIG. 4 and FIG. 5. The condition section of a rule includes a plurality of conditions of the basic information of a component. The output of the rule includes a plurality of machine parameters that are considered to be suitable to a combination of the plurality of conditions of the basic information of the component.

For example, K1_rule which indicates one of the conditions of the basic information in rule R1 indicates whether or not the component is larger than or equal to a certain size. In other words, the plurality of conditions of the basic information correspond to shape 15a, size 15b, etc. that are specified in basic information 15 of component data 14 illustrated in FIG. 3. The plurality of machine parameters correspond to nozzle settings 16a, suction 16d, etc. that are specified in machine parameter 16 of component data 14 illustrated in FIG. 3, and may be the values of the component data as they are or may include values which are updated by the user, or the like.

As described above, rule base 4 may include, for example, a rule that is entered by a vendor as illustrated in FIG. 4, or may include, for example, a rule that is entered by a user as illustrated in FIG. 5. In other words, a rule may be added by the user.

As illustrated in FIG. 4, in rule base 4, rules R1, R2, and R3 that are entered by the vendor are set such that machine parameters can be output for basic information of any components. More specifically, when a rule is entered by a vendor, a combination of the conditions of the basic information is set so as to cover the basic information of any components, and all machine parameters are set in the combination of the conditions of all such basic information.

On the other hand, in rule base 4, rule R4 added by the user may be a simple rule which includes only a condition that is a portion of the condition section of the basic information and a machine parameter that is a portion of the output, as illustrated in FIG. 5. In other words, when a rule is added by the user, there may be a portion of the condition section that is not set, as indicated by “NaN” in FIG. 4. This “NaN” means that the shape can be any shape as long as the other conditions of the condition section, such as the external shape, are satisfied. In other words, when the component data satisfies the other conditions of the condition section that have been set, rule R4 is applied.

It should be noted that the user inputs a rule to rule base 4 via interface section 8 illustrated in FIG. 1, for example. In other words, interface section 8 has a function of an inputter that is used when a rule is input to rule base 4 by the user. In addition, interface section 8 may also have a function of a display that displays the rules included in rule base 4 or input by the user. Furthermore, interface section 8 may display the machine parameters to be applied to a new component output by calculation processor 7 and the machine parameters actually used by component loading device 13 to perform the component loading operation. It should be noted that, as the function of the display, only the rules added by the user may be displayed.

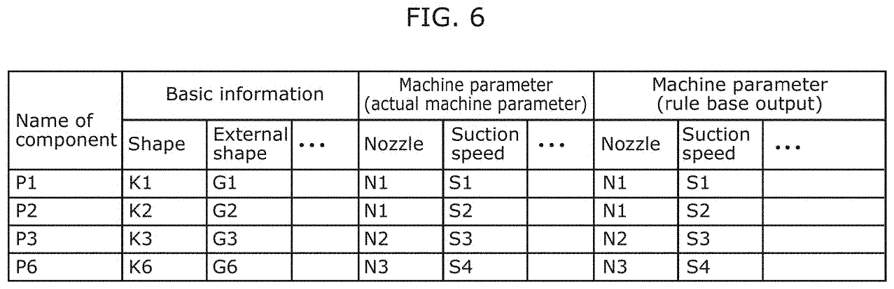

FIG. 6 is a diagram illustrating an example of actual training data 6 according to the present embodiment.

As described above, server 3 includes calculation processor 7 as illustrated in FIG. 1. Calculation processor 7 is, for example, an example of the estimator, and selects, as actual training data, component data that corresponds to an operation result that exceeds a predetermined reference, from operation information aggregators 10a and 10b.

According to the present embodiment, calculation processor 7 of server 3 selects, as actual training data 6, component data that corresponds to an operation result that exceeds a predetermined reference, from operation information aggregators 10a and 10b of client terminals 9A and 9B. Here, the predetermined reference is, for example, a performance of 90%. For this reason, the component data that corresponds to an operation result that exceeds a predetermined reference is also referred to as component data with good performance in the following description. More specifically, server 3 downloads (acquires), from the operation information aggregation data included in client terminals 9A and 9B, basic information of a component regarding the component data with good performance and a machine parameter (actual machine parameter) that is a machine parameter actually applied (used) in a component loading operation. It should be noted that, in FIG. 6, an example of the case in which component data with a performance that exceeds 90% is the component data with good performance is indicated. In other words, in FIG. 6, basic information and machine parameters (actual machine parameters) regarding components P1 to P3 and P6, among components P1 to P6 illustrated in FIG. 2, are accumulated as actual training data 6.

In addition, as illustrated in FIG. 6, server 3 adds, for the basic information and machine parameters (actual machine parameters) of the components having component data with good performance acquired as described above, rule base output values for the basic information of the respective components, and accumulates them as actual training data. It should be noted that the rule base output value is a machine parameter corresponding to the basic information of each component obtained by referring to rule base 4, and is indicated as a machine parameter (rule base output) in FIG. 6.

In addition, calculation processor 7 (estimator) of server 3 estimates at least one machine parameter of a new component, using actual training data 6, rule base 4, and the basic information of the new component. According to the present embodiment, when an input of the basic information of a new component is received, calculation processor 7 of server 3 first registers the basic information in component library 5, and then obtains the rule base output for the new component by referring to rule base 4. Then, using both the rule base output and actual training data 6, calculation processor 7 estimates and outputs an appropriate machine parameter.

Calculation processor 7 performs a calculation process based on Bayesian estimation so as to estimate an appropriate machine parameter. More specifically, calculation processor 7 performs estimation for the basic information of a new component, using a Gaussian process model (Gaussian process regressor) that has been learned using, as learning data, the basic information of the component and the corresponding machine parameter value which are included in the component data that corresponds to an operating result that exceeds a predetermined reference. In this manner, calculation processor 7 generates a predictive distribution of machine parameters that can be applied to the new component. Here, the normal distribution in which the machine parameter that can be applied to the new component is the mean generates the rule base output. With this, calculation processor 7 calculates a posterior distribution of the machine parameters that can be applied to the new component, and outputs the mean of the calculated posterior distribution as the machine parameter to be applied to the new component among the machine parameters that can be applied.

In addition, calculation processor 7 of server 3 registers, in component library 5, the appropriate machine parameters that have been output. Then, component library 5a, for example, of the component mounting line in which the component is used downloads the component data, thereby enabling component loading device 13 to use the component data for production.

### [Operation of Mounted Board Manufacturing System 1]

Next, an operation of mounted board manufacturing system 1 configured as described above will be described.

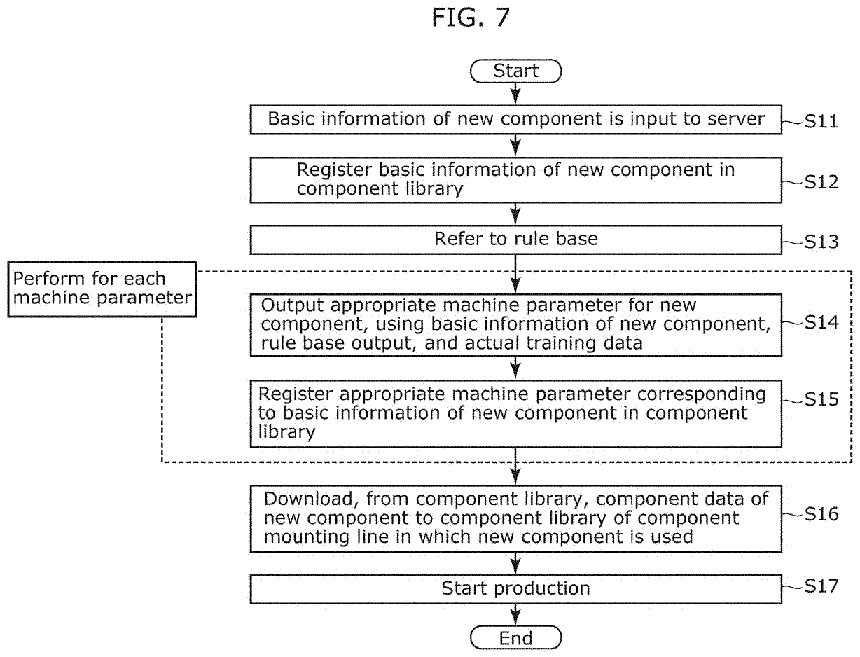

FIG. 7 is a flowchart illustrating the operation of mounted board manufacturing system 1 up to the start of production of new components.

First, assume that basic information of a new component is input to server 3 by a user, or the like (S11). Then, server 3 registers (sets) the basic information of the new component in component library 5 (S12).

Next, server 3 refers to rule base 4 using the basic information of the new component (S13), and obtains a rule base output for the new component.

Next, server 3 estimates and outputs an appropriate machine parameter for the new component, using the basic information of the new component, the rule base output, and actual training data 6 (S14). In this manner, server 3 estimates an appropriate machine parameter for the new component with a hybrid method in which both the rule base output and actual training data 6 are used.

Next, in component library 5, server 3 registers the appropriate machine parameter that has been output in step S14, in a position corresponding to the basic information of the new component (S15).

Next, for example, client terminal 9A downloads, from the component library of server 3, component data of the new component to component library 5a of component mounting line 12A in which the new component is used (S16).

Then, component mounting line 12A starts production of the new component using the component data of the new component (S17).

### [Advantageous Effects, etc.]

As described above, with mounted board manufacturing system 1 according to the present disclosure, it is possible to estimate an appropriate machine parameter for a new component, without the need for a man-hour to check the performance. In addition, mounted board manufacturing system 1 according to the present disclosure estimates an appropriate machine parameter by a hybrid method in which both a rule included in rule base 4 and a model that has been learned using actual training data 6 are used. This yields an advantageous effect that a machine parameter that cannot be covered by the rule alone is estimated by a model using the actual training data, and a machine parameter that cannot be covered by the model using the actual training data alone is estimated using the rule. Accordingly, mounted board manufacturing system 1 according to the present disclosure is capable of estimating, before the component loading operation, an appropriate machine parameter for a new component in accordance with the experience of a vendor and a skilled user, without the need for a man-hour to check the performance. Therefore, even in a situation where a new component that has no production record is used, it is not necessary to preliminarily take operation time for a component loading operation every time a component is changed, and thus it is possible to inhibit a decrease in production efficiency.

### Working Example 1

In Working example 1, one specific aspect of a calculation process based on Bayesian estimation, which is performed by calculation processor 7 of the server will be described. According to the present working example, calculation processor 7 uses a statistical model to estimate an appropriate machine parameter. It should be noted that, in the following description, boldface is assumed to indicate a vector or a matrix. In addition, in the following description, although a method of estimating one machine parameter MP1 will be explained, the same process will be applied to any machine parameters.

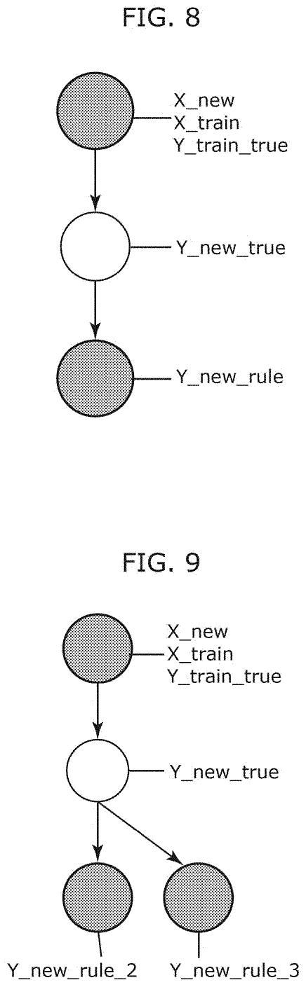

FIG. 8 is a diagram illustrating an example of a graphical model of the statistical model according to Working example 1 of the embodiment.

In FIG. 8, the basic information of a new component is X_new_vec (boldface), the name of a rule applied to the new component is Rule 1, and an output thereof (rule base output) is Y_new_rule. In addition, an appropriate machine parameter MP1 of the new component estimated by calculation processor 7 is Y_new_true. The basic information of n components of the actual training data is X_train_mat (boldface), and machine parameter MP1 of the actual training data is Y_train_true_vec (boldface).

Here, X_new_vec (boldface), X_train_mat (boldface), and Y_train_true_vec (boldface) can be expressed as below.

X_new_vec=[X_test₁ . . . X_testₘ] [Math. 1]

$$\begin{matrix}X\_train \_mat = [ \begin{matrix}{X\_train}_{11} & … & {X\_train}_{1 m} \\ ⋮ & ⋱ & ⋮ \\ {X\_train}_{n 1} & … & {X\_train}_{n m}\end{matrix} ] & [ Math . 2 ] \\ Y\_train \_true \_vec = [ \begin{matrix}Y\_train {\_true}_{1} \\ ⋮ \\ Y\_train {\_true}_{n}\end{matrix} ] & [ Math . 3 ]\end{matrix}$$

Each element of X_new_vec (boldface) indicates the basic information of a new component, each element of X_train_mat (boldface) indicates the basic information of a plurality of components of the actual training data, and each element of Y_train_true_vec (boldface) indicates the actual parameters of n components of the actual training data. In each of these elements, m indicates a total number of types of component information.

First, learning of a Gaussian process regression model is performed using X_train_mat (boldface) as an input and Y_train_true_vec (boldface) as an output.

After the learning of the regression model, when X_new_vec (boldface) is used as an input for the Gaussian process regression model, the output of the Gaussian process regression model is considered to be the predictive distribution of Y_new_true. It is known that the predictive distribution of the Gaussian process regression model is a normal distribution, and the mean and variance are analytically obtained.

The predictive distribution of Y_new_true is indicated in Expression 1 below. In Expression 1, the mean of the predictive distribution is Y_new_true_gaussian and the variance is σ_gaussian_r². In addition, as indicated in Expression 2 below, it is assumed that Y_new_rule_1 that is the rule base output for the new component is generated from the normal distribution in which Y_new_true is the mean and σ_r_1² is the variance.

Y_new_true˜N(Y_new_true_gaussian,σ_gaussian_r²) (Expression 1)

Y_new_rule_1˜N(Y_new_true,σ_r_1²) (Expression 2)

Here, the standard deviation σ_r is the mean obtained after converting, to absolute values, all of the elements of Y_train_true_vec_rule_1 (boldface) indicated below that is obtained by subtracting Y_new_rule1 from all of the elements of Y_train_true_vec (boldface), or twice the mean.

### [Math. 4]

$$Y\_train \_true \_vec \_rule \_ 1 = [ \begin{matrix}Y\_train {\_true}_{1} - Y\_new \_rule \_ 1 \\ ⋮ \\ Y\_train {\_true}_{n} - Y\_new \_rule \_ 1\end{matrix} ] \qquad [ Math . 4 ]$$

It should be noted that, an advantageous effect is yielded which, when the accuracy of rule 1 applied to the new component is low, the standard deviation σ_r automatically increases, and rule 1 becomes less important in the estimation performed by calculation processor 7 in the present working example.

In addition, when obtaining the posterior distribution of Y_new_true, the prior distribution of Y_new_true is set as a normal distribution in Expression 1, and the normal distribution in which Y_new_true is the mean is set in Expression 2. Accordingly, a conjugate prior distribution can be set for Y_new_true.

As described above, when values other than Y_new_true are known in Expression 1 and Expression 2, the posterior distribution of Y_new_true becomes a normal distribution, and the mean and variance of the posterior distribution can be analytically calculated. Accordingly, calculation processor 7 is capable of outputting the mean of the posterior distribution of Y_new_true as an appropriate machine parameter for the new component to be estimated, by calculating the mean of the posterior distribution of Y_new_true.

It should be noted that, in regard to a hyperparameter of the Gaussian process regression model that produces the output of Expression 1, for example, when learning is performed using the basic information of a plurality of components of the actual training data as X_train_mat (boldface) and Y_train_true_vec (boldface) that indicates machine parameter MP1 of the actual training data as the training data, a prior distribution may be set and Bayesian estimation may be performed, or maximum likelihood estimation of the second type may be performed.

In addition, the method of outputting the predictive distribution of Expression 1 is not limited to the case of using a Gaussian process regression model, but may be any method as long as the predictive distribution of Y_new_true can be output with the method, such as a Bayesian deep neural network or a Bayesian statistical model.

In addition, the distribution in which Y_new_true is the mean in Expression 2 is not limited to a normal distribution, but may be any distribution as long as Y_new_true is a parameter (population). In other words, it is sufficient if the distribution is a distribution with a machine parameter that can be applied to the new component to be estimated is used as the parameter. It should be noted that, at this time, when the posterior distribution of Y_new_true cannot be analytically calculated, Y_new_true that maximizes the posterior probability may be obtained and output as an appropriate machine parameter. Alternatively, the Markov Chain Monte Carlo method may be used to perform sampling from the posterior distribution, and the mean of the samples that have been obtained may be output as an appropriate machine parameter.

### Working Example 2

Rule base 4 held by server 3 may include two or more rules that do not match, in a plurality of rules for a new component that are used to calculate at least one machine parameter. In this case, one specific aspect of the calculation process based on Bayesian estimation performed by calculation processor 7 of the server will be explained as Working example 2. It should be noted that the following describes Working example 2 with a focus on the differences from Working example 1.

FIG. 9 is a diagram illustrating an example of a graphical model of the statistical model according to Working example 2 of the embodiment.

There are instances where two rules that produce different rule base outputs are present in rule base 4 for a new component to be estimated. In this case, the names of the two rules are Rule 2 and Rule 3, and the outputs thereof (rule base outputs) are Y_new_rule_2 and Y_new_rule_3, as illustrated in FIG. 9.

In addition, as illustrated in Expression 3 indicated below, for Y_new_rule_2, a normal distribution in which Y_new_true and σ_r_2² in Expression 3 are a mean and a variance, respectively, is assumed. In addition, as illustrated in Expression 4 indicated below, for Y_new_rule_3, a normal distribution in which Y_new_true and σ_r_3² in Expression 4 are a mean and a variance, respectively, is assumed. Furthermore, it is assumed that Y_new_true is generated from the normal distribution of Expression 1 described above, assuming that a normal distribution with a mean of a predictive distribution is Y_new_true_gaussian and a variance is σ_gaussian_r² is indicated.

Y_new_rule_2˜N(Y_new_true,σ_r_2²) (Expression 3)

Y_new_rule_3˜N(Y_new_true,σ_r_3²) (Expression 4)

In such a case, first, a normal distribution which is the posterior distribution of Y_new_true indicated in Expression 5, and in which effects of actual training data and rule 2 are taken into consideration can be analytically calculated from Expression 1 and Expression 3.

Y_new_true˜N(Y_new_true_gaussian_and_rule1,σ_gaussian_and_rule1²) (Expression 5)

Next, from Expression 4 and Expression 5, a normal distribution which is the posterior distribution of Y_new_true in which effects of actual training data and rule 3 are taken into consideration can be analytically calculated.

From the above, it is possible to obtain statistics that permit the presence of a plurality of rules with rule base outputs that do not match, by performing calculation as described above. With this, calculation processor 7 is capable of calculating appropriate machine parameters even when there are two rules that produce different rule base outputs for the new component to be estimated in rule base 4. As a result, it is possible for a user to easily set a new rule without considering the matching with the rule that have already been set by a vendor in rule base 4.

It should be noted that, among a plurality of rules, only a single or multiple high-order rules with a small σ_r may be used in performing the above-described calculation.

### Working Example 3

A method in which, when two or more rules that do not match are present in rule base 4, the two or more rules that do not match are reflected in a statistical model by recursively updating the statistical model using each of the two or more rules that do not match has been described in Working example 2. However, the present disclosure is not limited to this example. When there are two or more rules that do not match in rule base 4, the user may adjust a weight at the time of reflecting the rules in the statistical model. The following describes this case as Working example 3. It should be noted that the following describes Working example 3 with a focus on the differences from Working example 1 and Working example 2.

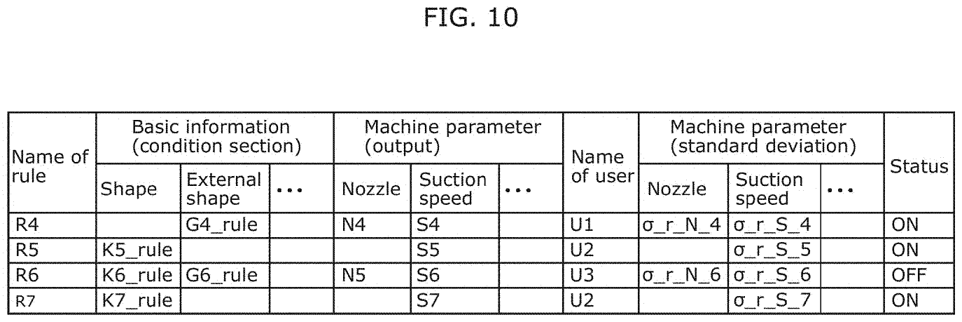

FIG. 10 is a diagram for explaining adjustment of weight of a plurality of rules included in rule base 4 according to Working example 3 of the embodiment.

In FIG. 10, the standard deviation of a statistical model that has been learned is indicated for a plurality of rules which are included in rule base 4, by interface section 8. More specifically, as illustrated in FIG. 10, interface section 8 may display the standard deviation σ_r of each of the rules, together with the condition section and output of the rule in rule base 4.

Here, for example, when a user wishes to put importance on a specific rule, it can be done by changing (setting) the standard deviation σ_r of the rule to a small value in interface section 8. This allows the statistical model to be updated to put importance on the rule set by the experience of a skilled user. As a result, it is possible to cause calculation processor 7 to estimate a machine parameter that is more appropriate for new component.

In addition, an example in which rule R7 is newly set when a specific skilled user U2 sets rule R5 is indicated in FIG. 10. In other words, in FIG. 10, a rule that depends on a user is indicated.

Here, for example, the standard deviation σ_r may be the same for some of the rules. In this case, for example, σ_r_S_7 that indicates the suction speed of rule R7 is calculated to be the mean of the absolute values of the difference between the actual suction speed in the actual training data and the output of rule R5 and the difference between the actual suction speed in the actual training data and the output of rule R7, or to be twice the mean.

In addition, a user may register a plurality of rules in rule base 4 via interface section 8, as indicated in the example illustrated in FIG. 10, before calculation processor 7 performs the calculation processing. Then, interface section 8 displays the standard deviation σ_r in each parameter of each of the rules. In this case, the user may, after checking the standard deviation σ_r of the rules, set ON or OFF via interface section 8. A rule that is set to OFF is not used for the above-described calculation processing performed by calculation processor 7. On the other hand, a rule that is set to ON is to be used for the above-described calculation processing performed by calculation processor 7.

### Working Example 4

In Working Examples 1 and 2, a normal distribution that generates a rule base output only for an appropriate machine parameter of a new component has been assumed. However, with the method in which a normal distribution is assumed, there are instances where an inappropriate estimation is performed when the appropriate machine parameter is not the only value but has a property of having a range. In view of the above, Gaussian process regression model A which is a Gaussian process regression model guided by a rule may be utilized instead of the Gaussian process regression model. It is possible to calculate an appropriate machine parameter, by replacing the Gaussian process of Working example 1 and Working example 2 with Gaussian process regression model A.

The following describes this case as Working example 4. It should be noted that the following describes Working example 4 with a focus on the differences from Working example 1 and Working example 2.

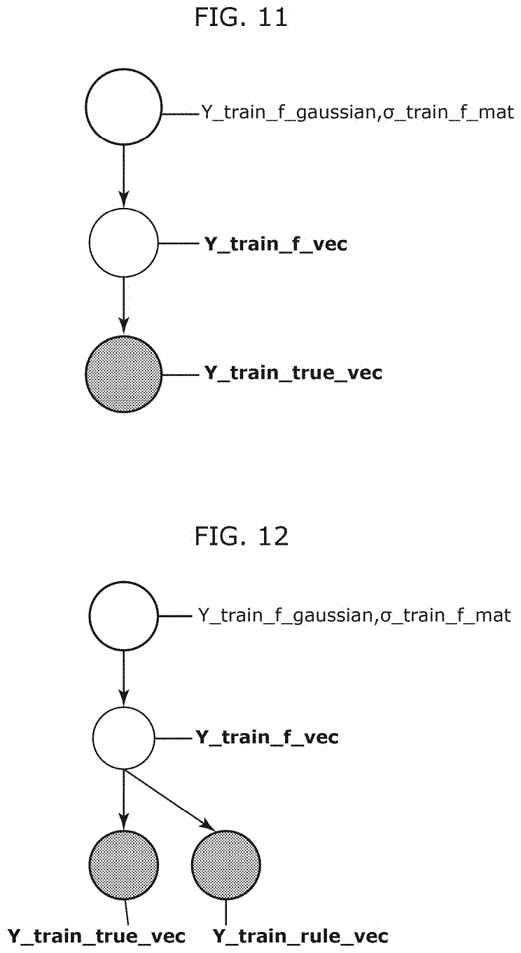

FIG. 11 is a diagram illustrating an example of a graphical model of a Gaussian process model. FIG. 12 is a diagram illustrating an example of a graphical model of the statistical model according to Working example 4 of the embodiment. The same names are applied to the same items as in FIG. 8, and detailed explanations will be omitted.

The following describes Gaussian process regression model A. First, assume that Y_train_true_vec (boldface) is generated from the Gaussian process regression model illustrated in Expression 6 and Expression 7. In Expression 6 and Expression 7, Y_train_f_vec (boldface) is a random variable, and Y_train_f_gaussian (boldface), σ_train_f_mat (boldface), and σ_gaussian correspond to parameters to be learned in the Gaussian process regression model. A general Gaussian process regression model has been described so far. The graphical model of this Gaussian process model is indicated as in FIG. 11.

Furthermore, assume that each element of Y_train_rule_vec (boldface) is generated from a normal distribution centered on each element of train_f_vec (boldface). Expression 8 indicates an example of this. In Expression 8, Y_train_rule_vec (boldface) is a vector in which an output of the rule corresponding to each component of the actual training data is stored. σ_r_[i] is the standard deviation of the corresponding rule. The graphical model of the model according to the present working example is indicated as in FIG. 12.

[Math. 5]

Y_train_f_vec˜N(Y_train_f_gaussian,σ_train_f_mat) (Expression 6)

[Math. 6]

Y_train_true_vec˜N(Y_train_f_vec,σ_gaussian) (Expression 7)

[Math. 7]

Y_train_rule_vec[n]˜N(train_f_vec[n],σ_r_[i]) (Expression 8)

Here, Y_train_true_vec (boldface) and Y_train_rule_vec (boldface) may be assumed to be known, and Y_train_f_gaussian (boldface), σ_train_f_mat (boldface), and σ_gaussian may be calculated to perform the learning. In addition, an inverse gamma distribution may be set as a prior distribution for σ_r_[i] to perform the learning. Then, Gaussian process regression model A obtained as a result of the learning is replaced with the Gaussian process of Working example 1 and Working example 2. As described above, it is possible to calculate an appropriate machine parameter even when the appropriate machine parameter has a property of having a range.

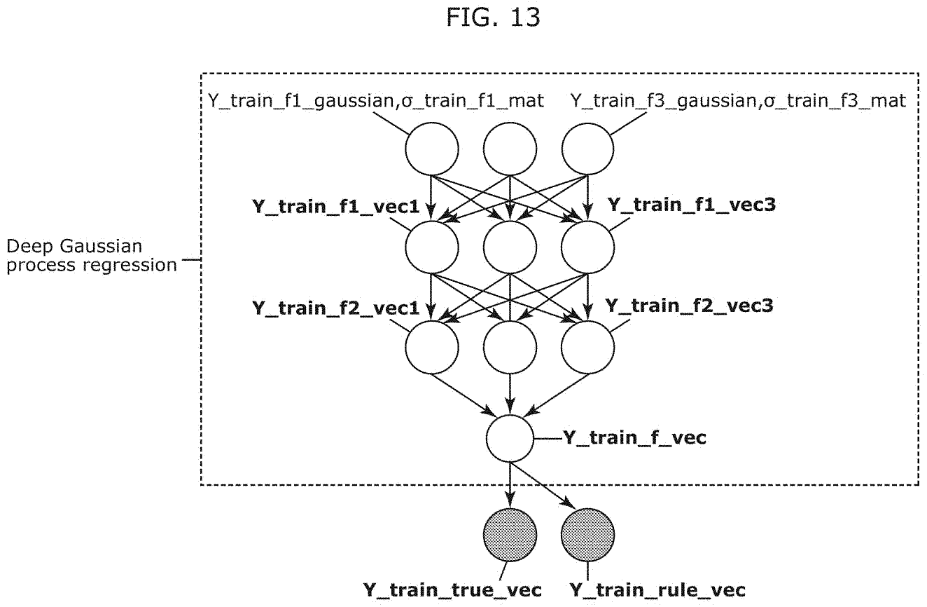

FIG. 13 is a diagram illustrating an example of another graphical model of the statistical model according to Working example 4 of the embodiment.

In addition, in Gaussian process regression model A, a deep Gaussian process regression which is a multi-layered Gaussian process regression may be used instead of the Gaussian process regression model. The graphical model for this case is indicated in FIG. 13. In FIG. 13, there are two hidden layers and a total number of units is three. However, the present disclosure is not limited to this example. In this manner, by using multiple layers of Gaussian process regression, it is possible to learn more complex relationships between component information and appropriate parameters.

### Working Example 5

In the embodiment and Working examples 1 through 4, machine parameters are described as quantitative variables. However, the present disclosure is not limited to this example. There may be the cases where, among a plurality of machine parameters, one or more machine parameters are qualitative variables that, for example, turn ON or OFF a function or the like of a certain device. The following describes one specific aspect of the arithmetic processing performed by calculation processor 7 of the server as Working example 5. It should be noted that the following describes Working example 5 with a focus on the differences from Working examples 1 through 4.

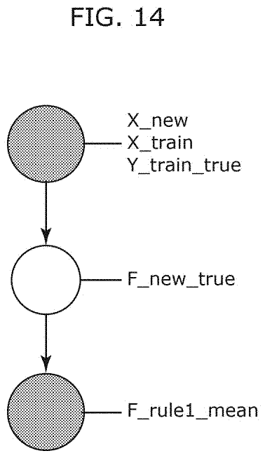

FIG. 14 is a diagram illustrating an example of a graphical model of the statistical model according to Working example 5 of the embodiment. For the items same as in FIG. 8, the same names are applied, and detailed explanations are omitted.

When the machine parameters are qualitative variables, learning of the statistical model is performed using the Gaussian process classifier corresponding to the qualitative variables instead of the Gaussian process regressor.

In the following description, a machine parameter which is a qualitative variable to be estimated by calculation processor 7 is referred to as MP2, and MP2 is assumed to have ON and OFF settings. In addition, MP2 is treated as 1 when it is ON, and as 0 when it is OFF.

When the Gaussian process classifier is applied, a latent variable vector F_train_true_vec (boldface) corresponding to Y_train_true_vec (boldface) which is machine parameter MP2 that is a qualitative variable of actual training data is introduced. Each element of Y_train_true_vec (boldface) and F_train_true_vec (boldface) is indicated as below.

$$\begin{matrix}Y\_train \_true \_vec = [ \begin{matrix}Y\_train {\_true}_{1} \\ ⋮ \\ Y\_train {\_true}_{n}\end{matrix} ] & [ Math . 8 ] \\ F\_train \_true \_vec = [ \begin{matrix}F\_train {\_true}_{1} \\ ⋮ \\ F\_train {\_true}_{n}\end{matrix} ] & [ Math . 9 ]\end{matrix}$$

In addition, the relationship between the respective elements of Y_train_true_vec (boldface) and F_train_true_vec (boldface) is indicated as Expression 9 below.

Y_train_true=σ(F_train_true) (Expression 9)

In Expression 9, function σ(z) is a function that converts a continuous value to a variable of from 0 to 1. Function σ(z) may be, for example, a logistic function indicated below.

$$\frac{1}{1 + exp ( - z )} \qquad [ Math . 10 ]$$

As illustrated in FIG. 14, with the Gaussian process classifier, when X_train_mat (boldface) and Y_train_true_vec (boldface) are given, learning such that F_train_true_vec (boldface) that outputs a value as close as possible to Y_train_true_vec (boldface) can be output from X_train (boldface) is performed on a statistical model. It should be noted that, unlike the Gaussian process regressor, it is difficult to analytically perform this learning due to the influence of function σ(z), and thus a method of performing the learning using Laplace approximation has been proposed.

As such, learning of the statistical model is performed using Laplace approximation. Then, after the learning of the statistical model using Laplace approximation, it is known that the normal distribution indicated in Expression 10 is output as the predictive distribution of F_new_true when X_new is an input.

F_new_true˜N(F_new_gaussian,F_σ_gaussian²) (Expression 10)

In the normal distribution indicated in Expression 10, the mean is F_new_gaussian and the variance is F_σ_gaussian².

Here, F_new_true is a latent variable of the new component that is to be estimated. For that reason, in the Gaussian process classifier, it is estimated that a machine parameter is ON when F_new_true is input to the function σ(z) and its output exceeds 0.5.

In the present working example, a known Gaussian process classifier is combined with a rule based output through the method described below. That is, first, prediction is performed on X_train_mat (boldface) using the Gaussian process classifier that has been learned in the above-described method, and F_train_true_pred_vec (boldface) indicated below is generated where each element is the mean of the latent variables to be output.

$$F\_train \_true \_pred \_vec = [ \begin{matrix}F\_train \_pred {\_true}_{1} \\ ⋮ \\ F\_train \_pred {\_true}_{n}\end{matrix} ] \qquad [ Math . 11 ]$$

Next, all the latent variables corresponding to the component whose element is 1 in Y_train_true_vec (boldface) indicated below are extracted from F_train_true_pred_vec (boldface), and the mean is assumed to be F_rule1_mean.

$$Y\_train \_true \_vec = [ \begin{matrix}Y\_train {\_true}_{1} \\ ⋮ \\ Y\_train {\_true}_{n}\end{matrix} ] \qquad [ Math . 12 ]$$

In addition, all the latent variables corresponding to the component whose element is 0 in Y_train_true_vec (boldface) indicated below are extracted from F_train_true_pred_vec (boldface), and the mean is assumed to be F_rule0_mean.

$$Y\_train \_true \_vec = [ \begin{matrix}Y\_train {\_true}_{1} \\ ⋮ \\ Y\_train {\_true}_{n}\end{matrix} ] \qquad [ Math . 13 ]$$

Here, a rule which outputs (rule base output) that machine parameter MP2 is ON is assumed to be R8.

At this time, the variance of R8 is denoted as F_rule1_dif². F_rule1_dif² is the mean obtained after converting, to absolute values, all of the elements of F_rule1_dif indicated below that is obtained by subtracting F_rule1_mean from all of the elements of F_train_true_pred_vec (boldface), or twice the mean.

$$F\_rule1 \_dif = [ \begin{matrix}F\_train \_true {\_pred}_{1} - F\_rule1 \_mean \\ ⋮ \\ F\_train \_true {\_pred}_{n} - F\_rule1 \_mean\end{matrix} ] \qquad [ Math . 14 ]$$

Next, as indicated in Expression 11 below, it is assumed that F_rule1_mean is generated from a normal distribution in which F_new_true is the mean and F_rule1_dif² is the variance.

F_rule1_mean˜N(F_new_true,F_rule1_dif²) (Expression 11)

As described above, from Expression 10 and Expression 11, when those other than F_new_true are known, the posterior distribution of F_new_true is a normal distribution, and its mean and variance can be analytically calculated.

Here, an output is assumed to be Y_new_true_probability when the mean of the posterior distribution of F_new_true is input to function σ(z). When Y_new_true_probability is greater than or equal to 0.5, an appropriate machine parameter is output as ON with Y_new_true=1. On the other hand, when Y_new_true_probability is smaller than 0.5, an appropriate machine parameter is output as OFF, with Y_new_true=0.

In this manner, calculation processor 7 is capable of outputting an appropriate machine parameter for a new component to be estimated, by calculating the mean of the posterior distribution of F_new_true as Y_new_true_probability, even when the machine parameter is a qualitative variable.

It should be noted that, although it has been described above that the machine parameter is a qualitative variable including two levels (two options), the present disclosure is not limited to this example. The machine parameter may be a qualitative variable and there may be a plurality of levels. In this case, it is sufficient if the above-described method is performed for each level in a one-versus-rest manner, and Expression 12 indicated below is calculated for each level with the posterior distribution of F_new_true as q(F_new_true).

[Math. 15]

Y_new_true_probability_map=∫σ(F_new_true)q

(F_new_true)dF_new_true (Expression 12)

When function σ(z) is a logistic function, the integral calculation is difficult. In this case, L samples which are finite may be sampled from q(F_new_true), each sample may be assigned to function σ(z), and the mean of the samples may be calculated as Y_new_true_probability_map. Then, it is sufficient if the level with the largest Y_new_true_probability_map is output as an appropriate machine parameter.

### Working Example 6

In addition, in the same manner as in the case where the machine parameter is quantitative, Gaussian process classifier A which is a Gaussian process classifier guided by a rule may be utilized in place of the Gaussian process classifier.

The following describes this case as Working example 4. It should be noted that the following describes Working example 4 with a focus on the differences from Working example 1 and Working example 2.

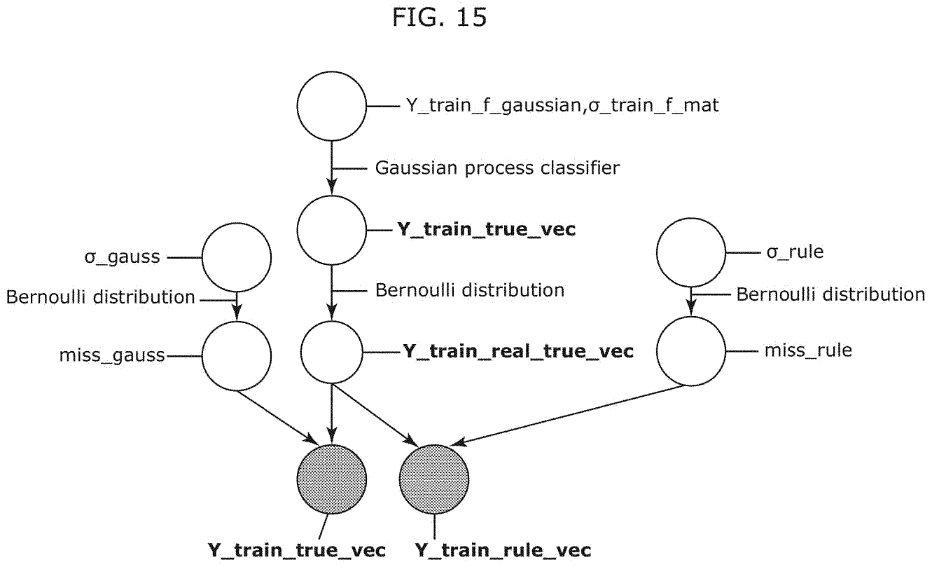

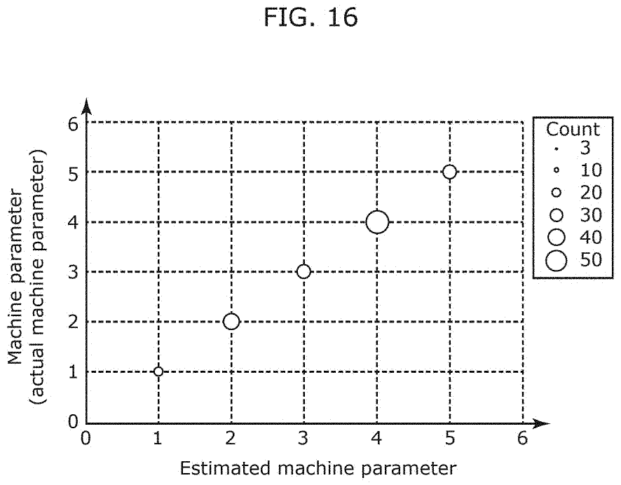

FIG. 15 is a diagram illustrating an example of a graphical model of the statistical model according to Working example 6 of the embodiment. For the items same as in FIG. 8, the same names are applied, and detailed explanations are omitted.

The following describes Gaussian process classifier A First, Y_train_true_vec (boldface) is assumed to be generated from the Gaussian process classifier indicated in Expression 13.

In addition, each element of Y_train_real_true_vec (boldface) is assumed to be generated from a Bernoulli distribution in which each element of Y_train_true_vec (boldface) is the population. Expression 14 indicates an example of this. In addition, using σ_rule[i] that is an error rate of a rule, whether or not the rule is erroneous is generated with a Bernoulli distribution, and is output as miss_rule[i]. A beta distribution is set for the prior distribution of the error rate of the rule. Expression 15 indicates an example of this. Furthermore, from noise σ_gauss, miss_gauss is generated from Bernoulli distribution. Expression 16 indicates an example of this. Furthermore, from Expression 17 and Expression 18, Y_train_true_vec (boldface) and Y_train_rule_vec (boldface) are calculated. The graphical model of such a model as described above is indicated as in FIG. 15.

[Math. 16]

Y_train_true_vec˜N(Y_train_c_gaussian,σ_train_c_mat) (Expression 13)

[Math. 17]

Y_train_real_true_vec[m]˜B(Y_train_true_vec[m]) (Expression 14)

miss_rule[i]˜B(σ_rule[i]) (Expression 15)

miss_gauss˜B(σ_gauss) (Expression 16)

[Math. 18]

Y_train_true_vec[n]=|Y_train_real_true_vec[m]·miss_gauss| (Expression 17)

[Math. 19]

Y_train_rule_vec[n]=|Y_train_real_true_vec[m]·miss_rule[i]| (Expression 18)

Here, Y_train_c_gaussian (boldface) and σ_train_c_mat (boldface) may be calculated with Y_train_true_vec (boldface) and Y_train_rule_vec (boldface) as being known, to perform the learning of the Gaussian process learning classifier. The Gaussian process learning classifier that has been learned in this manner may be replaced with the Gaussian process learning classifier in Working example 5, and used as Gaussian process learning classifier A.

Although the mounted board manufacturing system according to one or more aspects of the embodiment, etc. has been described so far, the present disclosure is not limited to this embodiment, etc. Those skilled in the art will readily appreciate that various modifications may be made in the present embodiment and that other embodiments may be obtained by arbitrarily combining the structural elements of the embodiments without materially departing from the novel teachings and advantages of the subject matter recited in the appended Claims. Accordingly, all such modifications and other embodiments are included in the present disclosure.

For example, in the hybrid method described in the embodiment, the basic information of a component used by rule base 4 and component information used by a machine learning model may be different. In this case, a user can create a simple rule using only a portion of the component information.

In addition, for example, the machine parameter estimated by the hybrid method described in the embodiment may be indicated by interface section 8 using a bubble chart.

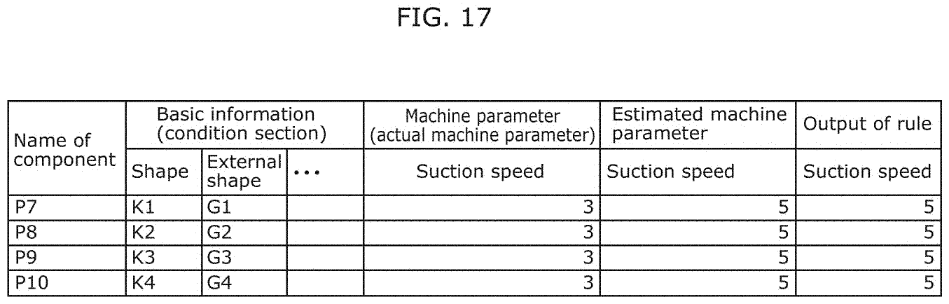

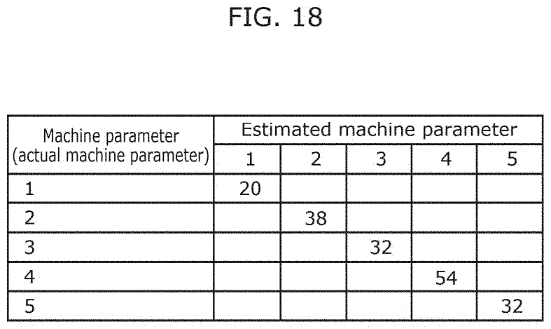

FIG. 16 is a bubble chart indicating machine parameters estimated by a hybrid method according to the present disclosure. FIG. 17 is component information indicated when one or more of the bubbles indicated in FIG. 16 are selected. FIG. 18 is a cumulative sum chart indicating machine parameters estimated by the hybrid method according to the present disclosure.

In other words, as to each machine parameter, the machine parameter of the actual training data and the machine parameter estimated by the hybrid method for each component may be indicated by a bubble chart as illustrated in FIG. 16. In FIG. 16, the size of a circle corresponds to a total number of components. In addition, the user may select one or more bubbles in FIG. 16 to view the component information as indicated in FIG. 17. In FIG. 16, the components on the diagonal are considered to be the components which are successfully estimated by the hybrid method, and the components that are way off the diagonal are considered to be the components that fail to be estimated.

It is possible for a user, by using such a bubble chart, to select a component that fails to be estimated and view the component information thereof, to obtain information for creating a new rule. In addition, the actual machine parameter can efficiently detect components which may possibly be inappropriate.

It should be noted that, when the machine parameter is not a continuous value but a qualitative variable, a cumulative sum chart may be shown as indicated as illustrated in FIG. 18.

### INDUSTRIAL APPLICABILITY

The present disclosure can be used for a mounted board manufacturing system that manufactures a mounted board, and in particular for a mounted board manufacturing system including a server, etc. that can estimate an appropriate machine parameter for a new component.

### REFERENCE SIGNS LIST

1 mounted board manufacturing system
2, 2a, 2b communication network
3 server
4 rule base
5, 5a, 5b component library
6 actual training data
7 calculation processor
8 interface section
9A, 9B client terminal
10a, 10b operation information aggregator
11a, 11b data communication terminal
12, 12A, 12B component mounting line
13, 13A1, 13A2, 13A3, 13B1, 13B2, 13B3 component loading device
14 component data
15 basic information
15a shape
15b size
15c component information
16 machine parameter
16a nozzle setting
16b speed parameter
16c recognition
16d suction
16e placement

What is claimed is:

1. A mounted board manufacturing system that manufactures a mounted board, which is a board mounted with a component, the mounted board manufacturing system comprising:
at least one component loading device that executes a component loading operation for loading the component on a board;
a rule base with which at least one machine parameter for executing the component loading operation performed by the at least one component loading device can be calculated;
an operation information aggregator that aggregates and accumulates, for each component data, results of processing executed by the at least one component loading device, together with operation information; and
an estimator that selects, as actual training data, component data that corresponds to an operation result that exceeds a predetermined reference, from the operation information aggregator, and estimates at least one machine parameter of a new component, using the actual training data, the rule base, and basic information of the new component.

2. The mounted board manufacturing system according to claim 1, wherein
the rule base includes two or more rules that do not match and that produce different outputs, for calculating the at least one machine parameter of the new component.

3. The mounted board manufacturing system according to claim 1, wherein
the estimator: performs an estimation on the basic information of the new component using a Bayesian statistical model to generate a predictive distribution of machine parameters applicable to the new component; calculates a posterior distribution of the machine parameters applicable to the new component based on a fact that an output of the rule base is generated from a distribution having, as parameters, the machine parameters applicable to the new component; and outputs a mean of the posterior distribution calculated, as a machine parameter to be applied to the new component among the machine parameters applicable to the new component.

4. The mounted board manufacturing system according to claim 2, wherein
the estimator:
performs an estimation on the basic information of the new component using a Bayesian statistical model that has been learned using, as learning data, basic information of a component and a corresponding machine parameter value that are included in the component data that corresponds to the operation result that exceeds the predetermined reference, to generate a predictive distribution of machine parameters applicable to the new component; calculates a posterior distribution of the machine parameters applicable to the new component based on a fact that outputs of the two or more rules that do not match are generated from a distribution having, as parameters, the machine parameters applicable to the new component; and outputs a mean of the posterior distribution calculated, as a machine parameter to be applied to the new component among the machine parameters applicable to the new component.

5. The mounted board manufacturing system according to claim 2, wherein
features of the component data that corresponds to the operation result that exceeds the predetermined reference are different between the rule base and machine learning.

6. The mounted board manufacturing system according to claim 2, further comprising:
an interface section that displays: a machine parameter that is output by the estimator and is to be applied to the new component; and a machine parameter that is actually used for executing the component loading operation performed by the at least one component loading device.
